(19) United States
(12) Patent Application Publication
(10) Pub. No.: US 2025/0176432 A1
(43) Pub. Date: May 29, 2025

(54) VIBRATION DEVICE AND VIBRATION METHOD THEREOF

(71) Applicant: TDK CORPORATION, Tokyo (JP)

(72) Inventors: Yuto TAKEUCHI, Tokyo (JP); Kaoru Kijima, Tokyo (JP)

(73) Assignee: TDK CORPORATION, Tokyo (JP)

(21) Appl. No.: 18/939,746

(22) Filed: Nov. 7, 2024

(30) Foreign Application Priority Data
Nov. 27, 2023 (JP) 2023-199871

(51) Int. Cl. H10N 30/20; H02J 50/10

(52) U.S. Cl. CPC H10N 30/20; H02J 50/10

(57) ABSTRACT

In the IC card, the first vibration pattern of the piezoelectric element when the separation distance between the reader-writer and the power receiving unit is short is different from the second vibration pattern of the piezoelectric element when the separation distance is longer. Therefore, the user can sense the difference in distance between the IC card and the reader-writer from the difference in vibration pattern. That is, the user may obtain information about the above separation distance, and increase of information communicated to the user is implemented.

### CROSS-REFERENCE TO RELATED APPLICATIONS

This application is based upon and claims the benefit of priority from Japanese Patent Application No. 2023-199871, filed on 27 November, 2023, the entire content of which is incorporated herein by reference.

### TECHNICAL FIELD

The present disclosure relates to a vibration device and a vibration method of the vibration device.

### BACKGROUND

Japanese Unexamined Patent Application Publication No. 2014-132404 discloses, as a kind of vibration device, a contactless IC card provided with a vibration mechanism. As a source of vibration in the vibration mechanism, a piezoelectric element or a motor for vibration is used.

### SUMMARY

The present inventors have studied a vibration pattern of the vibration device, and as a result, have newly found a technique for increasing information to communicate a user by the vibration pattern.

According to aspects of the present disclosure, a vibration device and a vibration method thereof increasing information to communicate a user are provided.

According to one aspect of the present disclosure, there is provided a vibration device including a power receiving unit configured to receive supply of contactless power from a power supply device, a control unit configured to generate a drive signal according to the power received at the power receiving unit, and a piezoelectric vibration element vibrating according to the drive signal generated at the control unit. A first vibration pattern of the piezoelectric vibration element when a separation distance between the power supply device and the power receiving unit receiving power supply is a first distance is different from a second vibration pattern of the piezoelectric vibration element when the separation distance is a second distance longer than the first distance.

According to one aspect of the present disclosure, there is provided a vibration method of a vibration device including a power receiving unit configured to receive supply of contactless power from a power supply device, a control unit configured to generate a drive signal according to the power received at the power receiving unit, and a piezoelectric vibration element vibrating according to the drive signal generated at the control unit. The piezoelectric vibration element vibrates in a first vibration pattern when a separation distance between the power supply device and the power receiving unit receiving power supply is a first distance, and the piezoelectric vibration element vibrates in a second vibration pattern different from the first vibration pattern when the separation distance is a second distance longer than the first distance.

In the above vibration device and the vibration method thereof, the vibration pattern of the piezoelectric vibration element is different whether the separation distance between the power supply device and the power receiving unit is the first distance or the second distance. Therefore, the user can sense from the difference in the vibration pattern whether the distance is the first distance or the second distance, and can obtain information on the separation distance.

### BRIEF DESCRIPTION OF THE DRAWINGS

FIG. 1 is a schematic perspective view showing an IC card according to one embodiment.

FIG. 2 shows how a user holds the IC card shown in FIG. 1 over a reader-writer.

FIG. 3 is an exploded perspective view showing a lamination structure of the IC card in FIG. 1.

FIG. 4 shows a vibration circuit of the IC card in FIG. 1.

FIG. 5 shows a behavior when the power supply to the IC card is appropriate.

FIG. 6 shows a behavior when the power supply to the IC card is weakened.

FIG. 7 shows a behavior when the power supply to the IC card is shortened.

### DETAILED DESCRIPTION

Hereinafter, embodiments of the present disclosure will be described in detail with reference to the accompanying drawings. In the description, the same reference numerals are used for the same elements or elements having the same functions, and redundant description will be omitted.

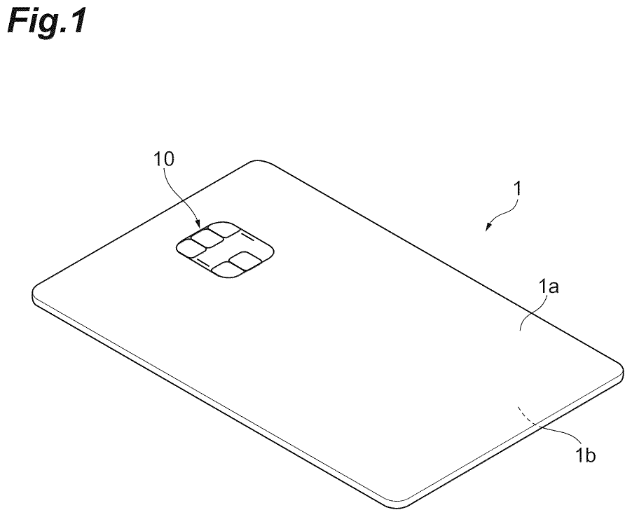

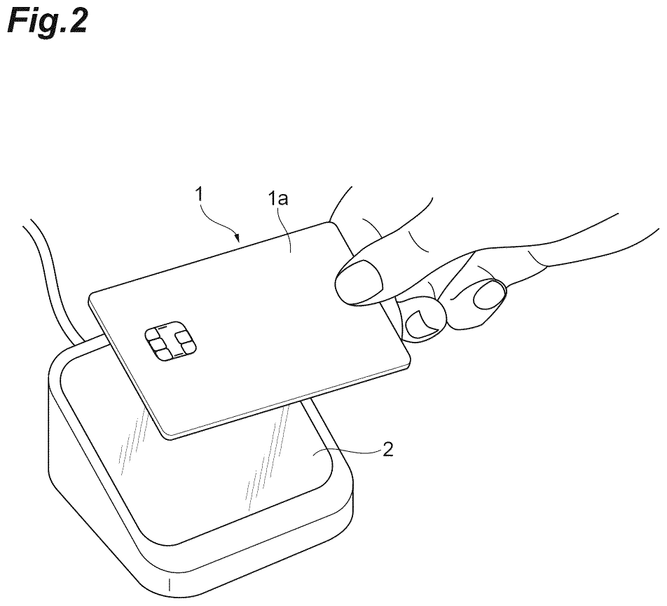

As a kind of the vibration device, an IC card shown in FIG. 1 is described for an example. The IC card 1 includes an embedded IC module 10 for performing arithmetic processing. The IC card 1 according to the present embodiment is a contactless type, and includes an antenna coil 16 to be described later is embedded. As shown in FIG. 2, the IC module 10 is held over a reader-writer 2 (i.e., kept away from the reader-writer 2 by a predetermined distance), which is a kind of power supply, so that the IC module 10 is supplied with contactless power from the reader-writer 2 and communicates with the reader-writer 2. The “contactless power supply” in the present specification includes contactless communication such as near field communication (NFC) in addition to power transmission.

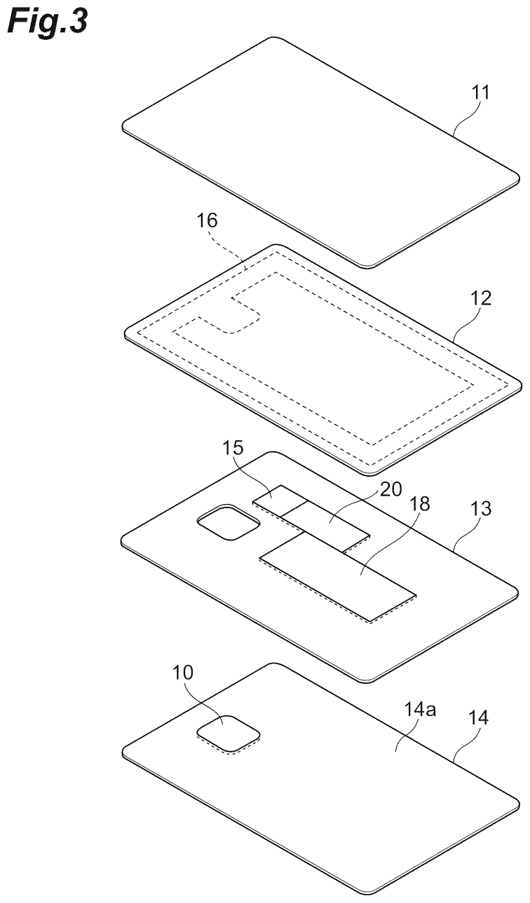

The IC card 1 has a plate-like outer shape, and has a front surface 1a and a back surface 1b. The IC module 10 is exposed in the front surface 1a. The IC card 1 has a lamination structure as shown in FIG. 3, which is laminated in the order of a plastic plate 11, an antenna sheet 12, a base substance 13, and a metal plate 14 from the back surface 1b side. Each interlayer of the IC card 1 is adhered by a known adhesion layer (for example, a double-sided adhesive tape, an adhesive material layer) which is not shown.

The plastic plate 11 is made of resin material that does not hinder the magnetic flux. The surface of the plastic plate 11 configures the back surface 1b of the IC card 1. The metal plate 14 is made of metal material such as stainless or titanium. The surface of the metal plate 14 configures the front surface 1a of the IC card 1. The IC module 10 is inleted in a part of a region of the metal plate 14.

The base substance 13 is a film made of insulating resin material, and can be configured by acrylic, for example. In the base substance 13, a voltage regulator 15, a piezoelectric element 18 and a control circuit 20 are mounted. The piezoelectric element 18 is a kind of piezoelectric vibration element, and the piezoelectric vibration element may be composed of a piezoelectric element, or may be composed of a piezoelectric element and a vibrating plate. The vibrating plate may be a plate made of resin or a plate made of metal. In the present embodiment, the piezoelectric element 18 is set in a through hole provided in the base substance 13 and is adhered to a rear surface 14a of the metal plate 14. The adhesive fixing of the piezoelectric element 18 to the metal plate 14 results in the transmission of displacement and vibration of the piezoelectric element 18 to the metal plate 14. That is, the vibration generated in the piezoelectric element 18 is transmitted from the inside to the surface of the IC card 1, and is directly sensed by the user of the IC card 1. The IC card 1 may vibrate wholly or locally in a part of the surface.

The antenna sheet 12 is made of insulating resin material or magnetic material. The antenna sheet 12 is provided with the antenna coil 16 including a coil pattern wound along the outer edge of the antenna sheet 12. The antenna coil 16 is electrically connected to the voltage regulator 15 of the base substance 13. The antenna coil 16 is magnetically connected to a coil in the IC module 10 of the metal plate 14.

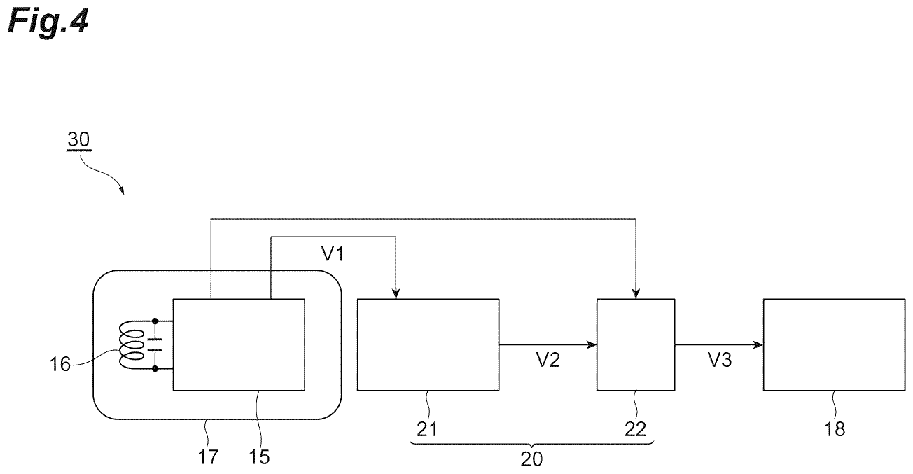

The IC card 1 has a vibration circuit 30. The configuration of the vibration circuit 30 is shown in FIG. 4. The vibration circuit 30 includes a power receiving unit 17 receiving contactless power supply from the reader-writer 2, a control circuit 20 (a control unit) generating a drive signal according to power received at the power receiving unit 17, and a piezoelectric element 18 vibrating according to the drive signal generated at the control circuit 20.

The power receiving unit 17 includes the voltage regulator 15 and the antenna coil 16. The power receiving unit 17 receives contactless power supply from the reader-writer 2 and outputs two types of drive voltages. The control circuit 20 includes a microcomputer 21 and a transistor 22 (specifically, field effect transistor (FET). The drive voltages are applied respectively to the microcomputer 21 and the transistor 22 from the power receiving unit 17. In the present embodiment, of the two types of drive voltages output from the power receiving unit 17, a drive voltage V1 (+5V as an example) applied to the microcomputer 21 is lower than a drive voltage (+14V as an example) applied to the transistor 22. The drive voltage applied to the transistor 22 may be output from a diode bridge in the power receiving unit 17. The transistor 22 performs a switching operation by a square-pulse drive signal V2 generated at the microcomputer 21 and generates a drive signal to be sent to the piezoelectric element 18. The piezoelectric element 18 vibrates with an element drive voltage V3 according to a square-pulse drive signal sent from the control circuit 20.

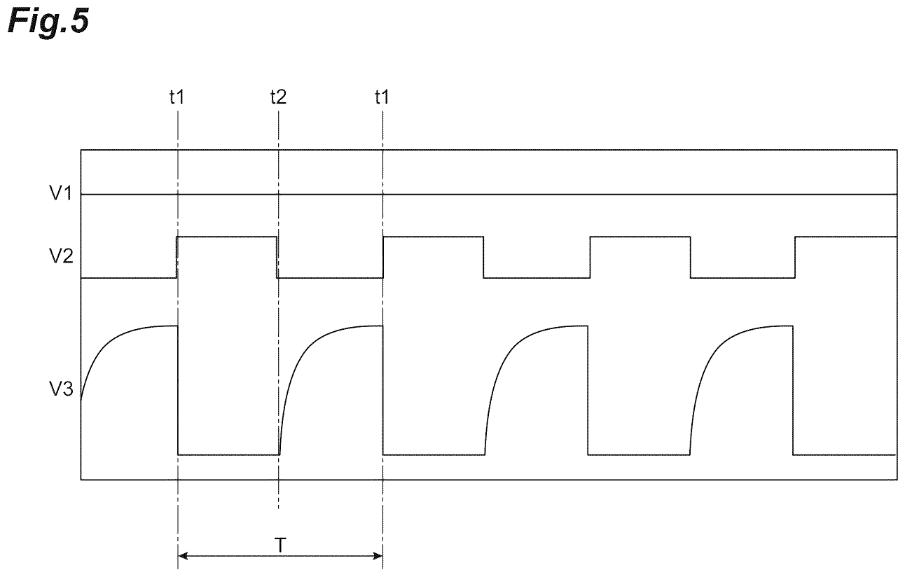

Next, ideals of the drive voltage V1, the drive signal V2, and the element drive voltage V3 will be described with reference to FIG. 5. FIG. 5 shows the behaviors of voltage, signal and vibration. In FIG. 5, the horizontal axis represents the progress of time and the vertical axis represents the amplitude. The drive voltage V1, the drive signal V2, and the element drive voltage V3 become ideal when the separation distance between the IC card 1 and the reader-writer 2 is sufficiently short (for example, direct contact at separation distance zero), and power supply from the reader-writer 2 to the IC card 1 is appropriately performed.

In the state of FIG. 5, the drive voltage V1 applied from the power receiving unit 17 to the microcomputer 21 of the control circuit 20 is always held at a constant value (for example, +5V). At this time, the drive signal V2 with ideal square pulse is generated at the microcomputer 21 of the control circuit 20. According to the drive signal V2 from the control circuit 20, the piezoelectric element 18 vibrates at the element drive voltage V3. Specifically, the piezoelectric element 18 elongates (or shrinks) in a timing t1 of the drive signal V2 rising, and then gradually shrinks (or elongates) in a timing t2 of the drive signal V2 falling, followed by vibration due to repetition of such elongation and shrinkage. A period T (as well as a frequency 1/T) of the piezoelectric element 18 is calculated by the interval of the timing t1 for starting elongation (or the interval of the timing t2 for starting shrinkage).

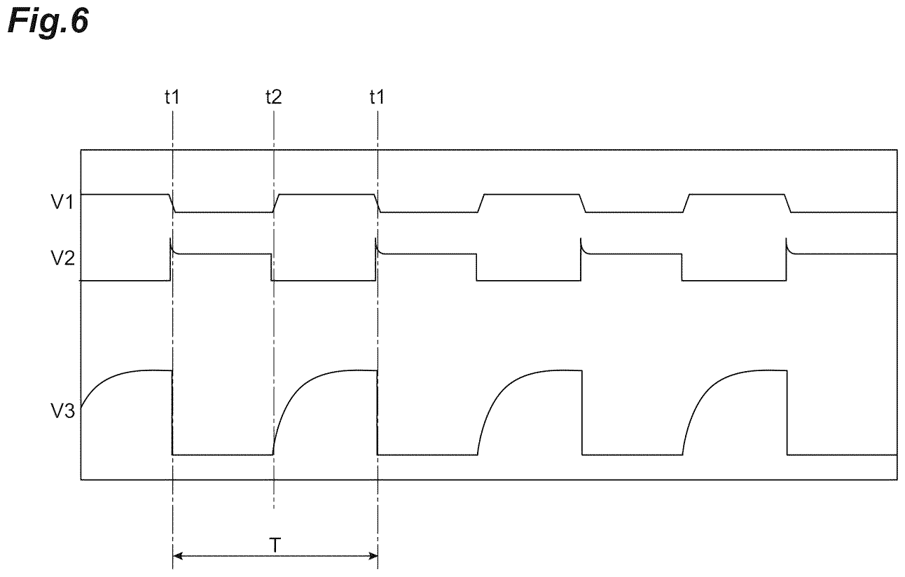

Next, FIG. 6 shows the behaviors of the voltage, the signal, and the vibration when the distance between the IC card 1 and the reader-writer 2 is slightly long (for example, separation distance 12 mm) and the power supply from the reader-writer 2 to the IC card 1 is weak. In the state of FIG. 6, the value of the drive voltage V1 applied from the power receiving unit 17 to the microcomputer 21 of the control circuit 20 is not a constant value, but is slightly reduced compared to the state of FIG. 5. Specifically, the drive voltage V1 is reduced in the timing t1 when the piezoelectric element 18 is elongated. In addition, a voltage of the drive signal V2 of the control circuit 20 falls. The piezoelectric element 18 vibrates in the same period T as in the state of FIG. 5, however the intensity of the vibration represented by the vertical axis is lower than the intensity in the state of FIG. 5.

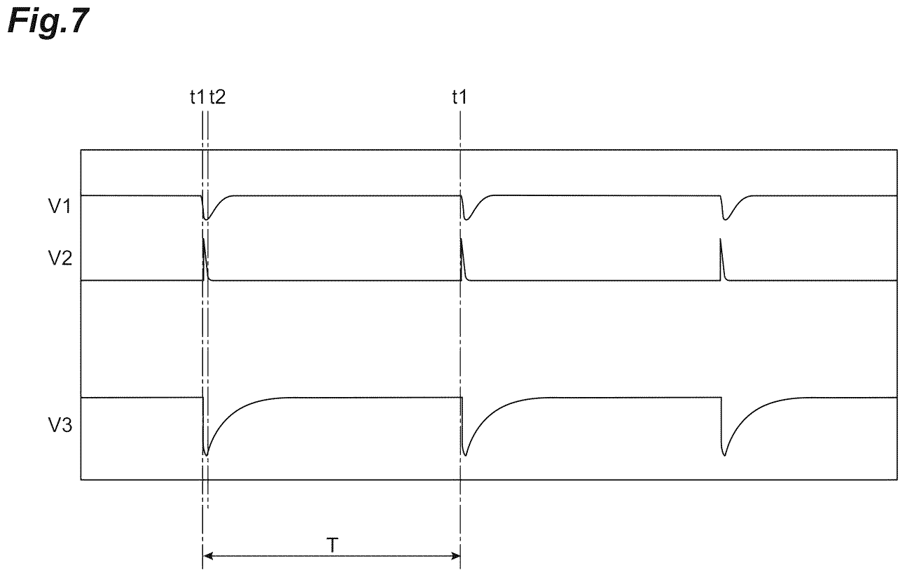

FIG. 7 shows the behavior of the voltage, the signal, and the vibration when the distance between the IC card 1 and the reader-writer 2 is long (for example, separation distance over 18 mm) and the power supply from the reader-writer 2 to the IC card 1 is shortened. In the state of FIG. 7, the value of the drive voltage V1 applied from the power receiving unit 17 to the microcomputer 21 of the control circuit 20 is not a constant value, but is further reduced compared to the state of FIG. 6. Specifically, the drive voltage V1 is greatly reduced in the timing t1 where the piezoelectric element 18 elongates. Accordingly, a sufficient amount of the drive voltage V1 is not applied to the microcomputer 21 in the control circuit 20, the microcomputer 21 stops temporarily in the timing t1, and the microcomputer 21 also returns in the timing t2 thereafter where the drive voltage V1 has returned. The intensity of the vibration of the piezoelectric element 18 represented by the vertical axis is lower than the intensity of the state of FIG. 5. Due to the power shortening and the stop of the microcomputer 21 accompanying the power shortening, in the piezoelectric element 18, the intensity of the vibration is weakened and the period T is extended (that is, the frequency is lowered) as compared with the states of FIGS. 5 and 6.

As described above, in the IC card 1, the vibration pattern (first vibration pattern) of the piezoelectric element 18 when the separation distance between the reader-writer 2 and the power receiving unit 17 is short (i.e., when the separation distance is a first distance) is different from the vibration pattern (second vibration pattern) of the piezoelectric element 18 when the separation distance is longer than the first distance (i.e., the separation distance is a second distance). In the present embodiment, the first vibration pattern of the piezoelectric element 18 when the separation distance is short as shown in FIG. 5 has a larger vibration intensity (amplitude) and a shorter period T than the second vibration pattern of the piezoelectric element 18 when the separation distance is long as shown in FIG. 7. Therefore, the user can sense the difference in the distance between the IC card 1 and the reader-writer 2 (for example, whether the distance is the first distance or the second distance) from the difference in the vibration pattern. That is, the user may obtain information about the above separation distance, and increase of information communicated to the user is implemented.

As long as the first vibration pattern and the second vibration pattern are different from each other, both the amplitude and the period of the vibration may be different from each other, or any one of the amplitude and the period of the vibration may be different from each other.

The present disclosure is not limited to the above embodiments and may be variously modified. For example, the vibration device is not limited to a form of a card, and may be a form of a small object or the like (i.e., fashion item, gadget, accessory, etc.). The power supply device is not limited to a reader-writer, and may be a payment terminal or the like.

What is claimed is:

1. A vibration device comprising:
a power receiving unit configured to receive supply of contactless power from a power supply device;
a control unit configured to generate a drive signal according to the power received at the power receiving unit; and
a piezoelectric vibration element vibrating according to the drive signal generated at the control unit,
wherein a first vibration pattern of the piezoelectric vibration element when a separation distance between the power supply device and the power receiving unit receiving power supply is a first distance is different from a second vibration pattern of the piezoelectric vibration element when the separation distance is a second distance longer than the first distance.

2. The vibration device according to claim 1, wherein the first vibration pattern and the second vibration pattern are different in at least one of amplitude and period.

3. The vibration device according to claim 2, wherein an amplitude of the first vibration pattern is greater than an amplitude of the second vibration pattern.

4. The vibration device according to claim 2, wherein a period of the first vibration pattern is shorter than a period of the second vibration pattern.

5. The vibration device according to claim 1, wherein the vibration device is an IC card.

6. A vibration method of a vibration device comprising a power receiving unit configured to receive supply of contactless power from a power supply device, a control unit configured to generate a drive signal according to the power received at the power receiving unit, and a piezoelectric vibration element vibrating according to the drive signal generated at the control unit,
wherein the piezoelectric vibration element vibrates in a first vibration pattern when a separation distance between the power supply device and the power receiving unit receiving power supply is a first distance, and the piezoelectric vibration element vibrates in a second vibration pattern different from the first vibration pattern when the separation distance is a second distance longer than the first distance.
